(19) United States
(12) Patent Application Publication
(10) Pub. No.: US 2024/0321911 A1
(43) Pub. Date: Sep. 26, 2024

(54) IMAGE SENSOR AND MANUFACTURING METHOD THEREOF

(71) Applicant: Samsung Electronics Co., Ltd., Suwon-si (KR)

(72) Inventors: Minkwan KIM, Suwon-si (KR); Joonhyuk HWANG, Suwon-si (KR); Jonghyun GO, Suwon-si (KR); Changkyu LEE, Suwon-si (KR)

(73) Assignee: Samsung Electronics Co., Ltd., Suwon-si (KR)

(21) Appl. No.: 18/537,644

(22) Filed: Dec. 12, 2023

(30) Foreign Application Priority Data
Mar. 24, 2023 (KR) 10-2023-0039123
Apr. 20, 2023 (KR) 10-2023-0052208

(51) Int. Cl. H01L 27/146

(52) U.S. Cl. CPC H01L 27/1462; H01L 27/14621; H01L 27/1463; H01L 27/14636; H01L 27/14645; H01L 27/14685

(57) ABSTRACT

An image sensor having a structure in which a light-blocking film having an excellent light-blocking effect is provided in a light-blocking region includes a first substrate including a first surface and a second surface, the first surface including a plurality of transistors, and the second surface being opposite to the first surface and configured to receive light, the first substrate comprising a pixel array region and a light-blocking region, an anti-reflection structure on the second surface of the first substrate in the pixel array region and the light-blocking region, and a light-blocking structure on the anti-reflection structure in the light-blocking region, wherein the light-blocking structure comprises a plurality of film that are sequentially stacked, the plurality of film including at least a first conductive film, a first insulating film, and a second conductive film.

### CROSS-REFERENCE TO RELATED APPLICATION

This U.S. non-provisional application claims the benefit of priority under 35 U.S.C. § 119 to Korean Patent Application Nos. 10-2023-0039123, filed on Mar. 24, 2023, and 10-2023-0052208, filed on Apr. 20, 2023, in the Korean Intellectual Property Office, the disclosures of each of which are incorporated by reference herein in their entireties.

### BACKGROUND

Various example embodiments of the inventive concepts relate to an image sensor, a system including the image sensor, and/or a method of manufacturing the image sensor, etc.

Image sensors are semiconductor devices that convert optical information (e.g., light, optical signals, etc.) into electric signals. Image sensors include a pixel array composed of a plurality of pixels arranged in two dimensions. Each of the pixels may include at least one photodiode. The photodiode converts incident light into an electric signal. The pixel array may include a pixel array region composed of pixels for generating image signals and a light-blocking region composed of reference pixels for generating reference signals of a dark level (e.g., optical black level, etc.). The image sensor may process the image signals with reference to the reference signals and generate final image signals. The light-blocking region may include a light-blocking film for blocking incident light so that the light is not transmitted to the reference pixels below and/or under the light-blocking region.

### SUMMARY

Various example embodiments of the inventive concepts provide an image sensor having a structure in which a light-blocking film having a light-blocking effect, improved light-blocking effect, and/or excellent light-blocking effect is provided in a light-blocking region.

Various example embodiments of the inventive concepts also provide a method of manufacturing an image sensor in which a light-blocking film having a light-blocking effect, an improved light-blocking effect, and/or an excellent light-blocking effect is provided in a light-blocking region.

However, the example embodiments of the inventive concepts are not limited thereto, and other advantageous and/or beneficial features of the example embodiments not described herein may be clearly understood by those skilled in the art from the following description.

According to at least one example embodiment of the inventive concepts, there is provided an image sensor including a first substrate including a first surface and a second surface, the first surface including a plurality of transistors, and the second surface being opposite to the first surface and configured to receive light, the first substrate comprising a pixel array region and a light-blocking region, an anti-reflection structure on the second surface of the first substrate in the pixel array region and the light-blocking region, and a light-blocking structure on the anti-reflection structure in the light-blocking region, wherein the light-blocking structure comprises a plurality of film that are sequentially stacked, the plurality of film including at least a first conductive film, a first insulating film, and a second conductive film.

According to at least one example embodiment of the inventive concepts, there is provided an image sensor including a first substrate including a first surface and a second surface, the first surface including a plurality of transistors, and the second surface is opposite to the first surface and is configured to receive light, the first substrate comprising a pixel array region and a light-blocking region, an anti-reflection structure on the second surface of the first substrate in the pixel array region and the light-blocking region, and a light-blocking structure on the anti-reflection structure in the light-blocking region, wherein the light-blocking structure comprises a plurality of film that are sequentially stacked, the plurality of film including at least a first conductive film, a first insulating film, and a second conductive film, and a plurality of color filters including filters of at least two colors, the plurality of color filters on the anti-reflection structure in the pixel array region, and the plurality of color filters are not on the light-blocking region.

According to at least one example embodiment of the inventive concepts, there is provided an image sensor including a first substrate including a first surface and a second surface, the first surface including a plurality of transistors, and the second surface opposite to the first surface and configured to receive light, the first substrate comprising a pixel array region and a light-blocking region, an anti-reflection structure on the second surface of the first substrate in the pixel array region and the light-blocking region, a light-blocking structure on the anti-reflection structure in the light-blocking region, the light-blocking structure comprising a plurality of film that are sequentially stacked, the plurality of film including at least a first conductive film, a first insulating film, and a second conductive film, a pixel isolation film configured to isolate photodiodes of unit pixels included in the first substrate of the pixel array region and the light-blocking region, and a contact region adjacent to the light-blocking region of the second surface of the first substrate, and the first conductive film is connected to a conductive pattern of the pixel isolation film in the contact region.

According to at least one example embodiment of the inventive concepts, there is provided an image sensor manufacturing method including forming a plurality of photoelectric conversion elements and a pixel isolation film on a first substrate, the pixel isolation film separating the photoelectric conversion elements from each other on the first substrate, the first substrate further including a pixel array region and a light-blocking region, forming, on a first surface of the first substrate, a plurality of transistors, a first interlayer insulating film, and a first line inside the first interlayer insulating film, forming, on a second substrate, a second interlayer film and a second line inside the second interlayer film, stacking and bonding the first substrate and the second substrate such that the first interlayer insulating film and the second interlayer film are brought into contact with each other, removing at least a portion of a second surface of the first substrate to expose the pixel isolation film, the second surface opposite to the first surface, forming an anti-reflection structure, the forming the anti-reflection structure including sequentially depositing at least three insulating films on the pixel isolation film and the second surface of the first substrate in the pixel array region and the light-blocking region, forming a first trench, the forming the first trench including etching the at least three insulating films and a portion of the first substrate in the light-blocking region, forming a first conductive film in the light-blocking region, the light-blocking region comprising the first trench and excluding the pixel array region, forming a metal pattern on the first conductive film in the first trench, and forming a first insulating film and a second conductive film above the metal pattern and the first conductive film in the light-blocking region.

### BRIEF DESCRIPTION OF THE DRAWINGS

Various example embodiments will be more clearly understood from the following detailed description taken in conjunction with the accompanying drawings in which:

FIG. 1 is a block diagram of an image sensor according to at least one example embodiment;

FIG. 2 is a configuration diagram of a stack structure of the image sensor according to at least one example embodiment;

FIG. 3 is a circuit diagram of a portion of a pixel array of the image sensor according to at least one example embodiment;

FIG. 4 is a plan view of the image sensor according to at least one example embodiment;

FIG. 5 is a cross-sectional view taken along line AA-AA′ of FIG. 4 according to at least one example embodiment;

FIG. 6 is an enlarged view of a region P1 of FIG. 5 and shows an anti-reflection structure according to at least one example embodiment;

FIG. 7 is an enlarged view of a region P2 of FIG. 5 and shows an anti-reflection structure and a light-blocking structure according to at least one example embodiment;

FIG. 8 is a graph showing light reflectivity (reflection) according to the thickness of an insulating film of the light-blocking structure according to at least one example embodiment;

FIG. 9A is a graph showing the reflection of the light-blocking structure according to at least one example embodiment;

FIGS. 9B and 9C are graphs showing the reflection according to angles of light incident to the light-blocking structure according to at least one example embodiment;

FIG. 9D is a graph showing light transmission of the light-blocking structure according to at least one example embodiment;

FIG. 10 is an enlarged view of a region P3 of FIG. 5 and shows films including a rear via stack according to at least one example embodiment;

FIG. 11 is a plan view showing a pattern of a second conductive film of a light-blocking structure according to at least one example embodiment; and

FIGS. 12A to 12J are cross-sectional views sequentially showing a method of manufacturing an image sensor, according to at least one example embodiment.

### DETAILED DESCRIPTION

Hereinafter, various example embodiments of the inventive concepts are described with reference to the accompanying drawings.

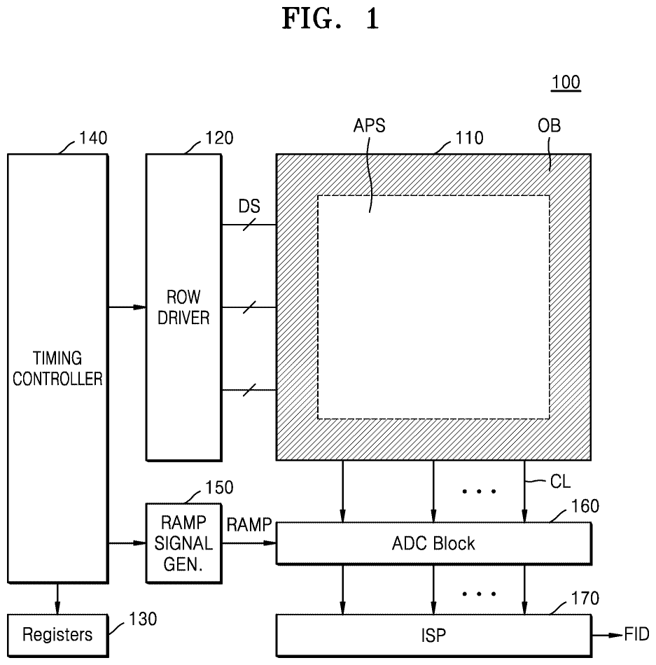

FIG. 1 is a block diagram of an image sensor 100 according to at least one example embodiment.

Referring to FIG. 1, the image sensor 100 may include a pixel array 110, a row driver 120, a mode setting register 130, a timing controller 140, a ramp signal generator 150, an analog to digital converter (ADC) block 160, and/or a signal processing unit 170, etc., but the example embodiments are not limited thereto, and for example, the image sensor 100 may include a greater or lesser number of constituent components. According to some example embodiments, the row driver 120, the mode setting register 130, the timing controller 140, the ramp signal generator 150, the analog to digital converter (ADC) block 160, and/or the signal processing unit 170, etc., may be implemented as processing circuitry. The processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

The pixel array 110 includes a pixel array region APS and/or at least one light-blocking region OB, etc. Each of the pixel array region APS and the light-blocking region OB may include a plurality of unit pixels arranged in two dimensions, and each of the unit pixels may convert an optical signal (e.g., incident light) into an electrical signal, but is not limited thereto. The unit pixels included in the pixel array 110 may output the electrical signal through a corresponding column line CL in response to a plurality of driving signals DS, such as a pixel selection signal, a reset signal, and/or a charge transfer signal, etc., from the row driver 120 in units of rows.

The row driver 120 may select and/or drive the pixel array 110 in units of rows. The row driver 120 decodes a row control signal (e.g., an address signal) received from the timing controller 140, generates the plurality of driving signals DS corresponding to the decoded row line, and/or transmit the generated signals to the pixel array 110, etc.

The mode setting register 130 is a register configured such that an application processor (AP), etc., connected to the image sensor 100 sets an operation mode of the image sensor 100 through an interface, but the example embodiments are not limited thereto. The AP may change an operation condition of the image sensor 100 in units of frames through the mode setting register 130, but is not limited thereto.

The timing controller 140 may control and/or collectively control the operation of each of the blocks (e.g., 120, 140, and/or 150, etc.) of the image sensor 100 according to and/or based on mode setting information that is set in and/or stored in the mode setting register 130.

The ramp signal generator 150 may generate a ramp signal RAMP that increases or decreases at a desired and/or certain rate and may provide the ramp signal RAMP to the ADC block 160, etc.

The ADC block 160 converts analog electric signals output from the column lines CL of the pixel array 110 into digital image signals through a correlated double sample method, but the example embodiments are not limited thereto, and other sampling methods may be used. In the correlated double sample method, a noise level and/or a signal level of a unit pixel transmitted to the column line CL are double sampled, and a difference level corresponding to the difference between the noise level and the signal level may be converted into a digital image signal, etc.

The signal processing unit 170 may process the received image signal and output the final image signal. The signal processing performed by the signal processing unit 170 may include, for example, noise reduction processing, gain adjustment, waveform shaping processing, interpolation processing, white balance processing, gamma processing, edge enhancement processing, binning, etc.

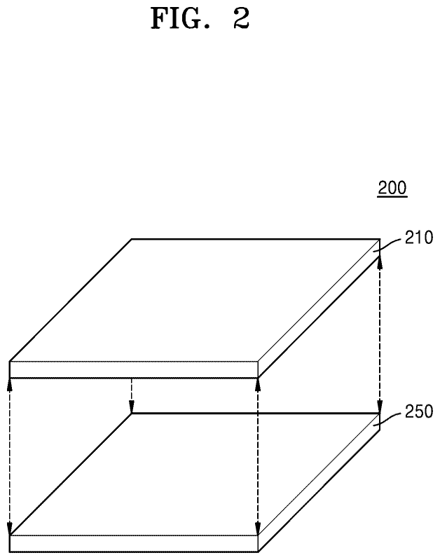

FIG. 2 is a configuration diagram of a stack structure of an image sensor 200 according to at least one example embodiment.

Referring to FIG. 2, the image sensor 200 includes two semiconductor substrates 210 and 250 (or referred to as a first semiconductor substrate 210 and a second semiconductor substrate 250), but is not limited thereto. The pixel array 110 of the image sensor 100 of FIG. 1 may be formed in the first semiconductor substrate 210, but is not limited thereto. All circuit blocks (e.g., blocks 120 to 170) except for the pixel array 110 of the image sensor 100 of FIG. 1 may be formed in the second semiconductor substrate 250, but is not limited thereto. The first semiconductor substrate 210 and the second semiconductor substrate 250 may be stacked vertically and transmit signals to each other through a through silicon via (TSV) that passes through the first semiconductor substrate 210 and/or a conductive connection types. In at least one example embodiment, the image sensor 200 may include three semiconductor substrates stacked on each other, but is not limited thereto. Photodiodes and transmission transistors of unit pixels included in the pixel array 110 may be included in and/or formed in a first semiconductor substrate. Other transistors included in the unit pixel other than the transmission transistors may be formed in a second semiconductor substrate positioned below the first semiconductor substrate, but the example embodiments are not limited thereto. The transmission transistors formed in the first semiconductor substrate and corresponding transistors formed in the second semiconductor substrate may be connected through the TSV or the like. One or more circuit blocks other than the pixel array 110 are arranged in a third semiconductor substrate below the second semiconductor substrate, and the third semiconductor substrate may be connected to the second semiconductor substrate through the TSV or the like, but the example embodiments are not limited thereto.

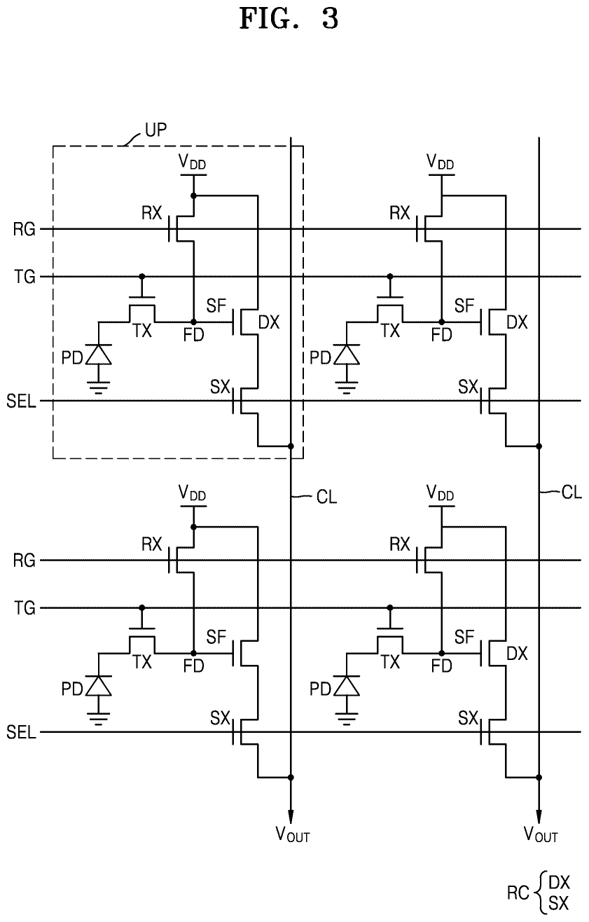

FIG. 3 is a circuit diagram of pixels included in a portion of the pixel array 110 of the image sensor 100 to which at least one example embodiment may be applied, but the example embodiments are not limited thereto.

Referring to FIGS. 1 and 3, the pixel array 110 may include a plurality of unit pixels UP, and the unit pixels UP may be two-dimensionally arranged in a matrix. Each of the unit pixels UP includes a photoelectric converter PD and/or a plurality of transistors, etc. The plurality of transistors may include a transmission transistor TX, a reset transistor RX, and/or a read circuit RC, etc. A read circuit RC may include a source follower transistor DX and/or a selection transistor SX, etc. Each of the unit pixels UP may further include a floating diffusion region FD commonly connected to the transmission transistor TX, the reset transistor RX, and/or the source follower transistor DX, but is not limited thereto.

The photoelectric converter PD generates and/or accumulates electric charges in proportion to the amount of external light incident to the photoelectric converter PD during an exposure time period. The photoelectric converter PD may include any one of a photodiode, a phototransistor, a photogate, a pinned photodiode, etc.

The transmission transistor TX may transfer electric charges accumulated during the exposure time (e.g., exposure time period) in the photoelectric converter PD to the floating diffusion region FD in response to a transmission control signal TG. The floating diffusion region FD may receive and/or store the accumulated electric charges from the photoelectric converter PD and form a voltage according to and/or based on the amount of the transferred electric charges.

The reset transistor RX may reset electric charges transferred to the floating diffusion region FD. A source of the reset transistor RX may be connected to the floating diffusion region FD and a drain thereof may be connected to a power supply voltage V_{DD}. When the reset transistor RX is turned on by a reset control signal RG, the power supply voltage V_{DD} of the drain of the reset transistor RX may be applied to the floating diffusion region FD to discharge the stored electric charges. Therefore, when the reset transistor RX is turned on, all electric charges transferred to the floating diffusion region FD are discharged, and thus, the voltage of the floating diffusion region FD may be reset to the power supply voltage V_{DD}.

The source follower transistor DX includes a gate connected to the floating diffusion region FD and a drain connected to the power supply voltage V_{DD} and may serve as a source follower buffer amplifier that generates an output voltage at a source of the source follower transistor DX in response to a gate voltage. The selection transistor SX may transmit a source voltage, which is an output of the source follower transistor DX, to the column line CL in response to a column selection signal SEL. That is, the read circuit RC may sense a change in voltage of the floating diffusion region FD and output an output voltage V_{OUT} to the column line CL.

In the unit pixel UP of FIG. 3, photoelectric converters PD and read circuits RC are in one-to-one correspondence with each other. However, in a unit pixel UP included in a high-resolution image sensor, a read circuit may be shared in a structure in which a plurality of photoelectric converters PD are commonly connected to a single floating diffusion region FD. Also, in the unit pixel UP of FIG. 3, the reset transistor RX and the floating diffusion region FD are directly connected to each other, but the example embodiments are not limited thereto. For example, another unit pixel UP for providing and/or securing a high dynamic range (HDR) may further include a conversion gain transistor for switching a conversion gain between the reset transistor RX and/or the floating diffusion region FD, etc.

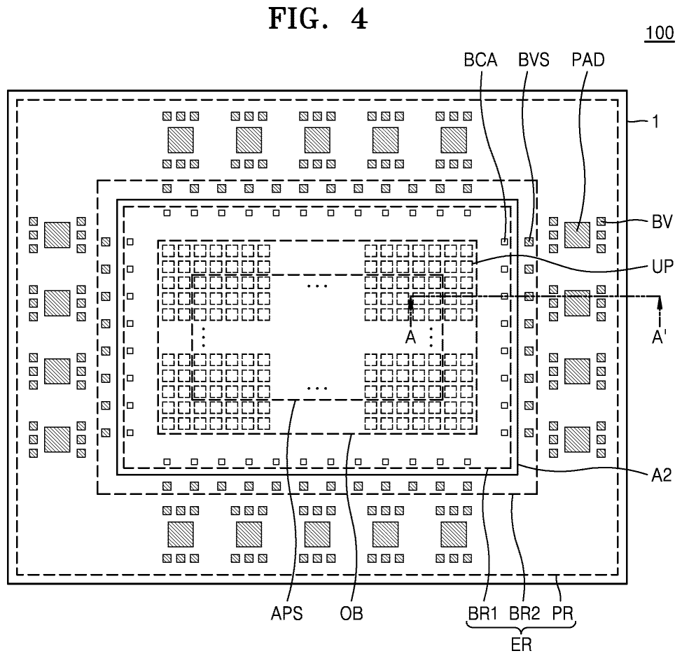

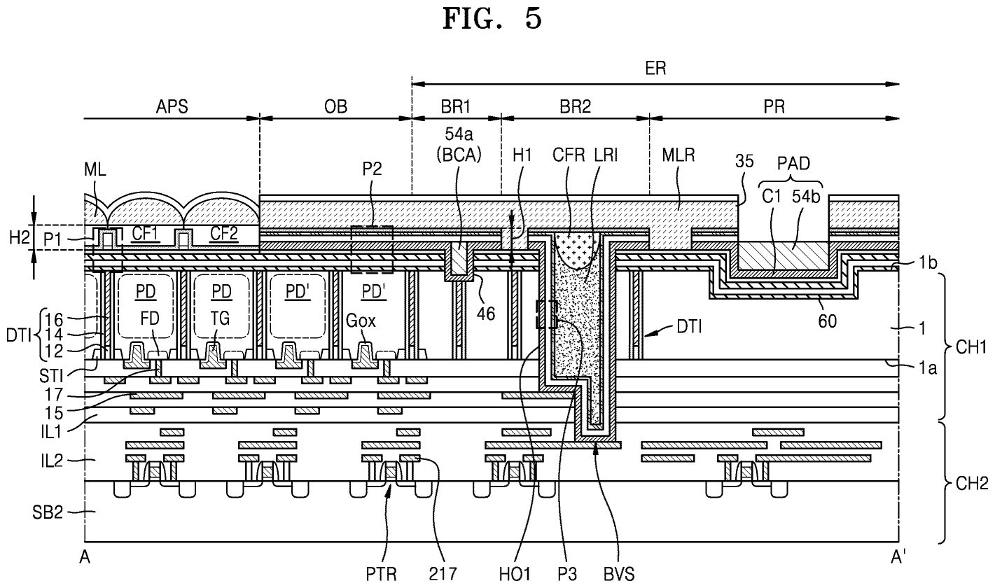

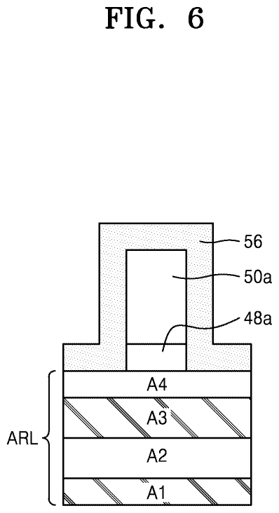

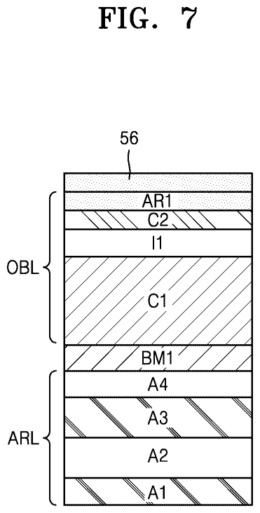

FIG. 4 is a plan view of the image sensor 100 according to at least one example embodiment. FIG. 5 is a cross-sectional view taken along line AA-AA′ of FIG. 4 according to at least one example embodiment. FIG. 6 is an enlarged view of a region P1 of FIG. 5 and shows an anti-reflection structure ARL, and FIG. 7 is an enlarged view of a region P2 of FIG. 5 and shows an anti-reflection structure ARL and a light-blocking structure OBL according to some example embodiments. A description is given below with reference to FIG. 1, but the example embodiments are not limited thereto.

Referring to FIGS. 4 and 5, the image sensor 100 may have a structure in which first and second sub chips CH1 and CH2 are stacked and bonded to each other, but is not limited thereto, and for example, the image sensor 100 may include a lesser or greater number of sub chips, the sub chips may not be stacked, and/or the sub chips may not be bonded, etc. The first sub chip CH1 may be on and/or disposed on the second sub chip CH2. The first sub chip CH1 includes a first substrate 1. The first substrate 1 may include, for example, a silicon single crystal wafer, a silicon epitaxial layer, and/or a silicon on insulator (SOI) substrate, etc. The first substrate 1 may be doped with, for example, first conductivity-type impurities. The first conductivity-type may include a P-type, but is not limited thereto. The first substrate 1 includes a front surface 1a and a rear surface 1b, which are opposite to each other. As used herein, the front surface 1a may also be referred to as a first surface and the rear surface 1b may also be referred to as a second surface.

The image sensor 100 may include a pixel array region APS, a light-blocking region OB, and/or an edge region ER in a plan view, but is not limited thereto. The first substrate 1 in each of the pixel array region APS and the light-blocking region OB may include a plurality of unit pixels UP therein. The light-blocking region OB may surround the pixel array region APS. The edge region ER may surround the light-blocking region OB. The edge region ER may include a contact region BR1, a rear via stack region BR2, and/or a pad region PR, etc. The rear via stack region BR2 may be located between the contact region BR1 and the pad region PR. The pad region PR may be located at the outermost region of the edge region ER, but is not limited thereto. In the rear surface 1b of the first substrate 1 in the edge region ER, the contact region BR1 may include rear contacts BCA, the rear via stack region BR2 may include rear via stacks BVS, and/or the pad region PR may include rear vias BV and rear conductive pads PAD, but are not limited thereto.

Pixel isolators DTI may be located in the first substrate 1 of the pixel array region APS and the light-blocking region OB to separate and/or limit regions of the unit pixels UP. The pixel isolators DTI may also be formed in the contact region BR1 and/or the rear via stack region BR2 of the edge region ER, etc. Each of the pixel separators DTI may have a mesh shape in a plan view, but are not limited thereto, and may have other shapes. The pixel isolator DTI is located in a deep trench that is formed from the front surface la to the rear surface 1b of the first substrate 1, but is not limited thereto. Depending on the process sequence of the image sensor 100, the formation direction of the pixel isolator DTI may be from the rear surface 1b to the front surface 1a of the first substrate 1, etc. Each of the pixel isolators DTI may include a buried insulating pattern 12, an isolation insulating pattern 14, and/or an isolation conductive pattern 16, but are not limited thereto. The buried insulating pattern 12 may be located between the isolation conductive pattern 16 and a first interlayer insulating film IL1. The isolation insulating pattern 14 may be located between the isolation conductive pattern 16 and the first substrate 1 and between the buried insulating pattern 12 and the first substrate 1.

The buried insulating pattern 12 and the isolation insulating pattern 14 may include insulating materials having different refractive indexes from the first substrate 1, but the example embodiments are not limited thereto. The buried insulating pattern 12 and/or the isolation insulating pattern 14 may include a semiconductor oxide material, for example, silicon oxide, but are not limited thereto. The isolation conductive pattern 16 may be apart from the first substrate 1. The isolation conductive pattern 16 may include film, such as a polysilicon film and/or a silicon germanium film, etc., doped with impurities. The impurities doped into the film, e.g., the polysilicon and/or silicon germanium film, may include, for example, one of boron, phosphorus, and arsenic, etc. Also, the isolation conductive pattern 16 may include a metal film.

The photoelectric converters PD may be doped with second conductivity-type impurities having opposite characteristics to the first conductivity-type impurities. The second conductivity-type may include an N-type, but is not limited thereto. The N-type impurities doped into the photoelectric converter PD establish a PN junction with the P-type impurities doped into the first substrate 1 near thereto to thereby form a photodiode.

In the first substrate 1, clement isolators STI may be located adjacent to the front surface 1a of the first substrate 1. The element isolators STI may be respectively penetrated by the pixel isolators DTI. The element isolators STI may define active regions in which transistors of the unit pixels UP are formed. That is, the active regions may be provided for transistors TX, RX, DX, and/or SX of the unit pixel UP, etc.

In each of unit pixels UP, a gate TG of the transmission transistor TX is on and/or disposed on the front surface la of the first substrate 1, but are not limited thereto. A portion of the gate TG of the transmission transistor TX may have a vertical shape that extends into the first substrate 1, etc. Also, the gate TG of the transmission transistor TX may be a planar type that does not extend into the first substrate 1 and instead has a flat shape, but the example embodiments are not limited thereto. A gate insulating film Gox is located between the gate TG and the first substrate 1. The floating diffusion region FD may be located on one side of the gate TG in the first substrate 1. The floating diffusion region FD may be doped with, for example, the second conductivity-type impurities, but is not limited thereto.

The image sensor 100 may include a rear light receiving image sensor. Light may be incident on a photodiode, which is a photoelectric converter PD formed in the pixel array region APS of the first substrate 1, through the rear surface 1b of the first substrate 1. Electron-hole pairs are generated by light incident on the photodiode, and electrons may accumulate in the photodiode. When a turn-on voltage is applied to the gate TG of the transmission transistor TX, the accumulated electrons may move to the floating diffusion region FD.

The first sub chip CHI further includes a first interlayer insulating film IL1 located on the front surface 1a. The first interlayer insulating film IL1 may include a multilayer of at least one selected from among a silicon oxide film, a silicon nitride film, a silicon oxynitride film, and/or a porous low-k dielectric film, etc. First lines 15 may be located between first interlayer insulating films IL1. The floating diffusion region FD may be connected to the first lines 15 through a first contact plug 17. The first contact plug 17 may pass through the first interlayer insulating film IL1 closest to the front surface 1a (e.g., the lowest layer) of the first substrate 1 among the first interlayer insulating films IL1 in the pixel array region APS.

The second sub chip CH2 may include a second substrate SB2, transistors PTR on and/or disposed thereon, and a second interlayer insulating film IL2 covering the second substrate SB2 and the transistors PTR, etc. Second lines 217 may be located in the second interlayer insulating film IL2. The second sub chip CH2 may include the circuit blocks (e.g., blocks 120 to 170) that process electrical signals of pixels into image signals through column lines CL of the pixel array 110 of the first sub chip CH1, but is not limited thereto.

Referring to FIGS. 5 and 6, the anti-reflection structure ARL may be on and/or disposed on the rear surface 1b of the first substrate 1. The anti-reflection structure ARL may be on and/or disposed entirely over the pixel array region APS, the light-blocking region OB, and the edge region ER. The anti-reflection structure ARL may not be provided in (e.g., may be omitted from) a rear contact BCA, a rear via stack BVS, and the pad region PR, but the example embodiments are not limited thereto.

The anti-reflection structure ARL may include one or more insulating films, such as a first insulating film A1, a second insulating film A2, a third insulating film A3, and/or a fourth insulating film A4 sequentially stacked on each other, but is not limited thereto. In at least one example embodiment, the first insulating film A1 may include aluminum oxide, the second insulating film A2 and the fourth insulating film A4 may include hafnium oxide, and the third insulating film A3 may include silicon oxide, but are not limited thereto. Also, one of the insulating films, e.g., the second insulating film A2, may be replaced with a conductive film, such as titanium oxide, etc. According to and/or based on the thickness and refractive index of each of the films, the anti-reflection structure ARL decreases and/or suppresses reflection of incident light and increases the amount of light incident to the photodiode. In at least one example embodiment, the thickness T1 of the first insulating film A1 and the thickness T4 of the fourth insulating film A4 are less than the thickness T2 of the second insulating film A2, but the example embodiments are not limited thereto. The thickness T2 of the second insulating film A2 may be equal to or less than a thickness T3 of the third insulating film A3, etc. According to at least one example embodiment, the first thickness T1 may be approximately 10 Å to approximately 100 Å (e.g., within +/−25% of 10 Å to +/−25% of 100 Å), but is not limited thereto. According to at least one example embodiment, the second thickness T2 may be approximately 300 Å to approximately 700 Å (e.g., +/−25% of 300 Å to +/−25% of 700 Å), but is not limited thereto. The third thickness T3 may be approximately 600 Å to approximately 900 Å (e.g., +/−25% of 600 Å to +/−25% of 900 Å), but is not limited thereto. The fourth thickness T4 may be approximately 20 Å to approximately 100 Å (e.g., +/−25% of 20 Å to +/−25% of 100 Å), but is not limited thereto.

One or more light-blocking grid patterns 48a may be arranged on the anti-reflection structure ARL in the pixel array region APS. Low refractive index grid patterns 50a are respectively on and/or disposed on the light-blocking grid patterns 48a. Each of the light-blocking grid pattern 48a and the low refractive index grid pattern 50a may have a mesh shape in a plan view and vertically overlap the pixel isolator DTI, but the example embodiments are not limited thereto, and for example, the light-blocking grid pattern 48a and/or the low refractive index grid pattern 50a may have a different shape. The light-blocking grid pattern 48a may include, for example, at least one of titanium and titanium nitride, etc., but is not limited thereto. The low refractive index grid pattern 50a may have a uniform thickness and/or may include an organic material having a low refractive index, but is not limited thereto.

A protective film 56 for decreasing and/or preventing moisture absorption is on and/or conformally disposed on the low refractive index grid patterns 50a and/or the anti-reflection structure ARL in the pixel array region APS, etc. A plurality of color filters, e.g., CF1 and CF2 (or referred to as a first color filter CF1 and a second color filter CF2), etc., are arranged between the low refractive index grid patterns 50a and on the protective film 56, but the example embodiments are not limited thereto. Each of the color filters, e.g., color filters CF1 and CF2, may have one color, such as blue, green, or red, but are not limited thereto. In another example, the color filters, e.g., color filters CF1 and CF2, may include other colors, such as cyan, magenta, yellow, etc. In the image sensor according to at least one example embodiment, the color filters, e.g., color filters CF1 and CF2, may be arranged in a bayer pattern, but are not limited thereto. In at least one example embodiment, the color filters CF1 and CF2 may be arranged in other patterns, such as a tetra pattern in a 2×2 arrangement, a nona pattern in a 3×3 arrangement, and/or a hexadeca pattern in a 4×4 arrangement, etc. The low refractive index grid pattern 50a may have a lower refractive index than the color filters CF1 and CF2, but is not limited thereto. For example, the low refractive index grid pattern 50a may have a refractive index of 1.3 or less, but is not limited thereto. The light-blocking grid pattern 48a and the low refractive index grid pattern 50a may decrease and/or prevent crosstalk between neighboring unit pixels UP.

The light-blocking structure OBL is on and/or disposed on the anti-reflection structure ARL in the light-blocking region OB of the first substrate 1. The light-blocking structure OBL blocks light incident to the photodiodes PD′ of reference pixels formed on the first substrate 1 in the light-blocking region OB. Each of the photodiodes PD′ of the reference pixels has the same structure as the photodiode, which is the photoelectric converter PD formed in the pixel array region APS, but do not perform the same operation as the photoelectric converter PD (e.g., the operation of receiving light and generating an electrical signal), etc., or in other words, the photodiodes PD′ are non-functional. That is, light is blocked to the photodiodes PD′ of the reference pixels, and thus, a dark level reference signal value may be generated in the photodiodes PD′. The signal processing unit 170 of FIG. 1 may compensate for a dark level of output values of the pixels of the pixel array region APS using the dark level reference signal value.

Referring to FIGS. 5 and 7, the light-blocking structure OBL includes at least a first conductive film C1, a second conductive film C2, and an insulating film I1 therebetween, but the example embodiments are not limited thereto, and for example, there may be a greater or lesser number of conductive films and/or insulating film, etc. The first conductive film C1, the insulating film I1, and the second conductive film C2 may form a metal-insulator-metal (MIM) resonator. A portion of the incident light may pass through the second conductive film C2 and the insulating film I1 and may be reflected from and/or absorbed by the first conductive film C1. The light reflected by the first conductive film C1 may be partially absorbed by the first insulating film I1. The remaining light that has not been absorbed by the insulating film I1 may be absorbed by the first conductive film C1. Energy of visible and near-infrared band light may be absorbed by a plasmon phenomenon on the surface of the first conductive film C1. That is, the MIM resonator may absorb an increased amount of incident light (e.g., most and/or all of the incident light) and decrease and/or minimize the amount of reflected light. As the light reflected from the light-blocking region OB is decreased and/or minimized, this may more likely decrease and/or prevent the quality of an image signal from being deteriorated due to a flare phenomenon that may occur in an image sensor.

Referring back to FIG. 7, the light-blocking structure OBL is on and/or disposed on the anti-reflection structure ARL. A barrier metal BMI may be provided between the light-blocking structure OBL and the fourth insulating film A4 of the anti-reflection structure ARL to improve adhesion strength, but the example embodiments are not limited thereto. The barrier metal BMI may include, e.g., titanium, etc. The thickness of the first conductive film C1 may be greater than the thickness of the second conductive film C2, but is not limited thereto. For example, the thickness of the first conductive film C1 may be at least 10 times greater than the thickness of the second conductive film C2, but is not limited thereto. In at least one example embodiment, in order to decrease and/or minimize transmittance of incident light, the thickness of the first conductive film C1 may be, for example, greater than 100 nm and the thickness of the second conductive film C2 may be, for example, less than 50 nm, but the example embodiments are not limited thereto. The first conductive film C1 may include a metal material, such as tungsten (W), etc., but is not limited thereto. The second conductive film C2 may include a metal material, such as titanium (Ti), etc., but is not limited thereto.

The thickness of the insulating film I1 of the light-blocking structure OBL may be determined based on and/or according to the wavelength of light to be absorbed by the light-blocking structure OBL. The thickness of the insulating film Il when the image sensor 100 uses (e.g., captures and/or senses, etc.) RGB visible light may be less than the thickness of the insulating film I1 when the image sensor 100 uses (e.g., captures and/or senses) infrared light, etc. The insulating film I1 may include silicon oxide, but is not limited thereto.

An anti-reflection film AR1 and a protective film 56 may be disposed and/or sequentially disposed on the second conductive film C2 of the light-blocking structure OBL. For example, the anti-reflection film AR1 on and/or disposed on the second conductive film C2 may have a thickness that is ¼ or less of a wavelength of light to be absorbed by the light-blocking structure OBL, but is not limited thereto. Also, the anti-reflection film AR1 may include a plurality of films like the anti-reflection structure ARL, etc. The anti-reflection film AR1 may include hafnium oxide (HfOx), but is not limited thereto.

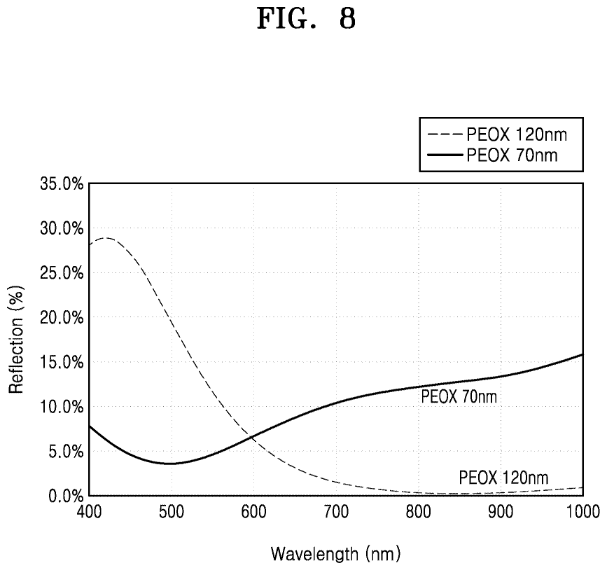

FIG. 8 is a graph showing reflectance (reflection) according to the thickness of the insulating film I1 provided in the light-blocking structure OBL according to at least one example embodiment of the inventive concepts.

Referring to FIG. 8, in a state in which the thicknesses of the first conductive film C1 and the second conductive film C2 are kept constant, the dashed line represents the reflectance when the thickness of the insulating film I1 is 120 nm and the solid line represents the reflectance when the thickness of the insulating film I1 is 70 nm, but the example embodiments are not limited thereto, and for example, the thickness of the insulating film may be different than 120 nm or 70 nm. It may be seen that the reflectance of the light-blocking structure OBL may be further lowered when the thickness of the insulating film I1 for blocking light in the near-infrared light region is greater than the thickness for blocking light in the visible light region. As the reflectance of the light-blocking structure OBL decreases, the light incident on the light-blocking region OB is absorbed instead of being reflected by the light-blocking structure OBL. That is, it can be seen that when the thickness of the insulating film I1 for absorbing visible light is less than the thickness of the insulating film I1 for absorbing infrared light, reflectance of light may be lowered and/or decreased, thereby improving image quality of image data captured by the image sensor, etc.

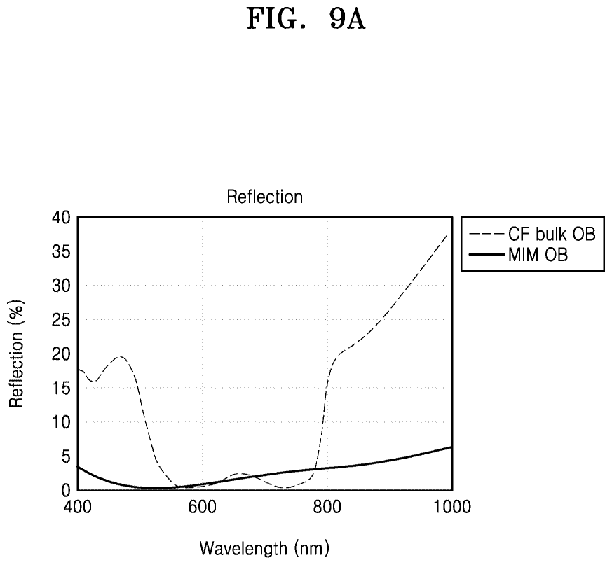

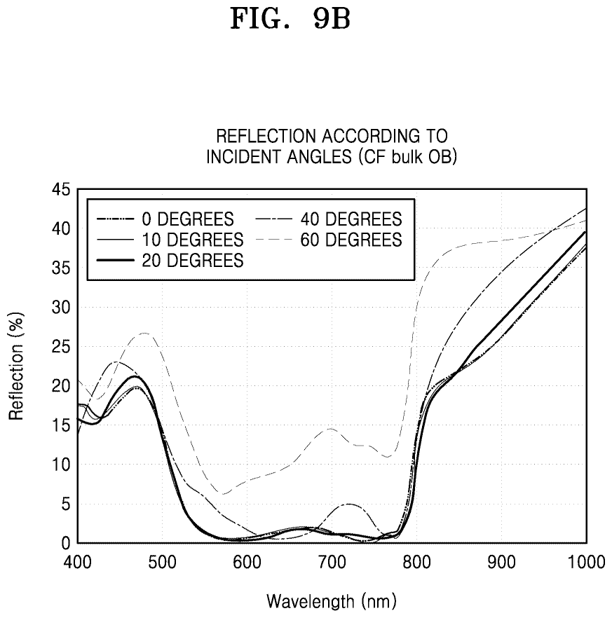

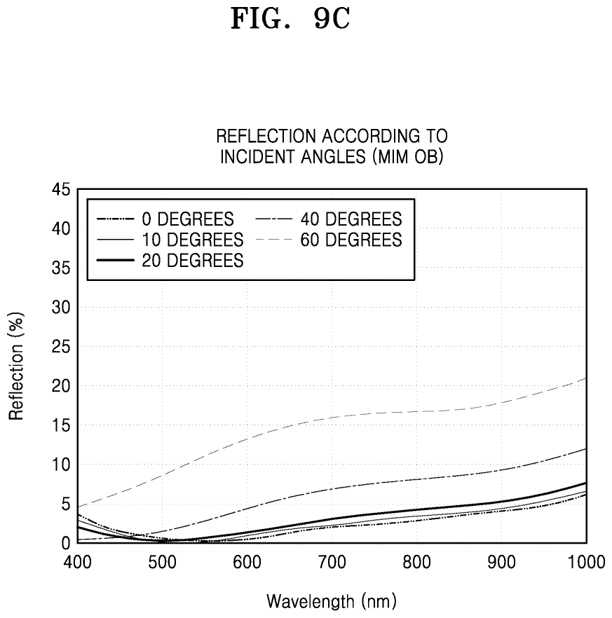

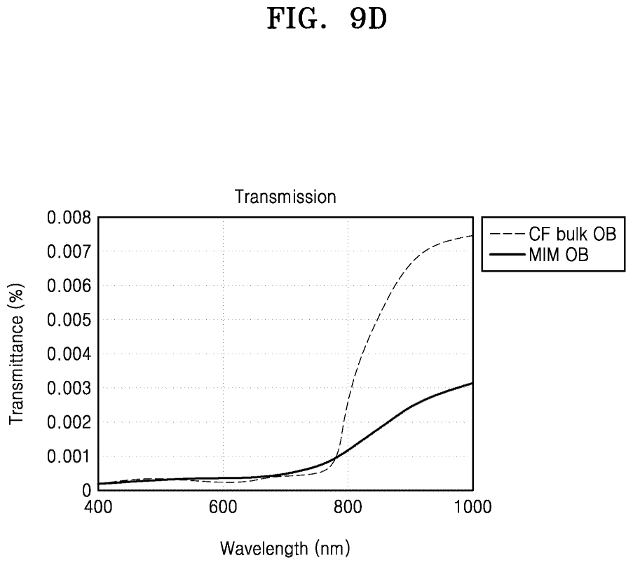

FIG. 9A is a graph showing the reflectance of the light-blocking structure OBL according to at least one example embodiment of the inventive concepts and the reflectance of a light-blocking structure according to the related art when the angle of incident light is 0 degrees. The light-blocking structure according to the related art has a structure that includes an insulating film between a single metal film and a color filter (e.g., an image sensor having a CF bulk OB structure, a CF bulk OB image sensor, etc.). In the graph, the reflectance of the light-blocking structure according to the related art is shown as a dashed line and the reflectance of the light-blocking structure OBL including the MIM resonator (e.g., an image sensor having a MIM OB structure, a MIM OB image sensor, etc.) according to at least one example embodiment of the inventive concepts is shown as a solid line.

Referring to FIG. 9A, in the entire range of wavelengths from the visible light region to the near-infrared light region when the angle of incident light is 0 degrees, it can be seen that the reflectance (e.g., MIM OB image sensor) of the light-blocking structure OBL according to at least one example embodiment of the inventive concepts is less than (e.g., lower than) the reflectance (e.g., CF bulk OB image sensor) of the light-blocking structure according to the related art. In particular, it can be seen that, in the near-infrared wavelength range, the reflectance (e.g., MIM OB image sensor) of the light-blocking structure OBL including the MIM resonator according to at least one example embodiment of the inventive concepts is at least three times less than the reflectance (e.g., CF bulk OB image sensor) of the light-blocking structure including a color filter according to the related art, but is not limited thereto.

FIGS. 9B and 9C are graphs showing the reflectance of the light-blocking structure according to the related art and the reflectance of the light-blocking structure according to at least one example embodiment of the inventive concepts at various angles of incident light.

Referring to FIGS. 9B and 9C, FIG. 9B shows the reflectance according to the related art (e.g., CF bulk OB image sensor) at a light incident angle of about 0 degrees to about 60 degrees, and FIG. 9C shows the reflectance of the light-blocking structure OBL including the MIM resonator (e.g., MIM OB image sensor) according to at least one example embodiment of the inventive concepts at a light incident angle of about 0 degrees to about 60 degrees. It can be seen that the reflectance of the light-blocking structure including the MIM resonator (e.g., MIM OB image sensor) according to at least one example embodiment of the inventive concepts is less, on average, than the reflectance according to the related art (e.g., CF bulk OB image sensor) in a range from visible light to near-infrared light over an incident angle of about 0 degrees to about 60 degrees, etc.

In the graph of FIG. 9D, the transmittance of the light-blocking structure according to the related art is shown as a dashed line and the transmittance of the light-blocking structure OBL including the MIM resonator according to at least one example embodiment of the inventive concepts is shown as a solid line.

Referring to FIG. 9D, in the entire range of wavelengths from the visible light region to the near-infrared light region when the angle of incident light is 0 degrees, it can be seen that the transmittance of the light-blocking structure OBL (e.g., MIM OB image sensor) according to at least one example embodiment of the inventive concepts is less than the transmittance of the light-blocking structure according to the related art (e.g., CF bulk OB image sensor). That is, the light-blocking structure OBL including the MIM according to at least one example embodiment of the inventive concepts may improve the dark level characteristics of reference pixels located in the light-blocking region OB by absorbing a larger amount of incident light and decreasing and/or minimizing the amount of transmitted light, etc.

Referring back to FIG. 5, a height HI of the light-blocking structure OBL on the rear surface 1b of the first substrate 1 may be the same and/or substantially the same (e.g., within +/−25%) as or lower than a height H2 of the color filters CF1 and CF2 on the rear surface 1b of the first substrate 1 in the pixel array region APS, but is not limited thereto. Therefore, after the light-blocking structure OBL and the color filters CF1 and CF2 are formed on the rear surface 1b of the first substrate 1, the height difference therebetween becomes decreased and/or minimized. Accordingly, it is possible to decrease and/or prevent defects in a subsequent process such as formation of a microlens.

Referring to FIGS. 4 and 5, the rear contact BCA passes through the anti-reflection structure ARL and is then placed inside a first rear trench 46 of the first substrate 1. Each of the rear contacts BCA may include a first conductive film C1 and a first metal pattern 54a, but is not limited thereto. For example, a barrier metal BM1 may be further provided below the first conductive film C1, etc. Also, the first conductive film C1 and the barrier metal BMI may conformally cover the side surface and the bottom of the first rear trench 46. The first metal pattern 54a may include, for example, aluminum, etc. The first conductive film C1 and the first metal pattern 54a may fill the first rear trench 46, but are not limited thereto. The rear contacts BCA may be connected to the isolation conductive pattern 16 of the pixel isolator DTI. The rear contacts BCA are connected to a rear conductive pad PAD by a first conductive film to receive a desired and/or certain voltage, for example, a ground voltage and/or a negative potential, etc., and apply the received desired and/or certain voltage to the isolation conductive pattern 16 of the pixel isolator DTI.

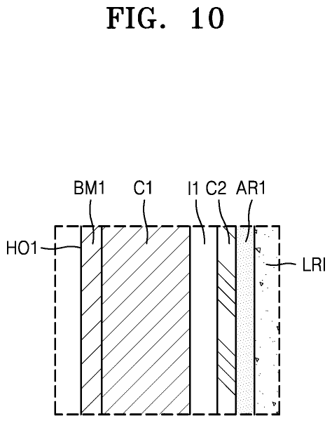

FIG. 10 is an enlarged view of a region P3 of FIG. 5 and shows films included in a rear via stack BVS according to some example embodiments.

Referring back to FIGS. 4, 5, and 10, rear via stacks BVS are respectively located in first holes HO1, but are not limited thereto. Each of the rear via stack BVS may pass through the anti-reflection structure ARL, the first substrate 1, and/or the first interlayer insulating film IL1, and may partially pass through the second interlayer insulating film IL2. In the rear via stacks BVS, the same layers as the light-blocking structure OBL including the first conductive film C1 may conformally fill the inner walls and bottoms of the first holes HO1. The rear via stacks BVS may electrically connect at least some of the first lines 15 of the first sub chip CH1 to at least some of the second lines 217 of the second sub chip CH2 using the first conductive film C1, but the example embodiments are not limited thereto. Each of the first holes HO1 may be filled with a low refractive index protective pattern LRI, and a capping pattern CFR may be arranged and/or disposed thereon, but the example embodiments are not limited thereto. A lens residual layer MLR may be above and/or disposed above the capping pattern CFR, but is not limited thereto.

Referring back to FIGS. 4 and 5, the rear conductive pad PAD is inside and/or disposed inside a second rear trench 60, but the example embodiments are not limited thereto. The rear conductive pad PAD may include a first conductive film C1 and/or a second metal pattern 54b, etc. The first conductive film C1 may conformally cover the side surface and bottom of the second rear trench 60. The second metal pattern 54b may include, for example, aluminum, but is not limited thereto. The second metal pattern 54b may fill the second rear trench 60.

Although not illustrated in FIG. 5, the rear vias BV of FIG. 4, like the rear via stacks BVS, may pass through the anti-reflection structure ARL, the first substrate 1, the first interlayer insulating film IL1, and/or a portion of the second interlayer insulating film IL2, etc. The rear vias BV may be connected to some of the second lines 217 without being connected to the first lines 15, but are not limited thereto. For example, the rear vias BV may be connected to the respective rear conductive pads PAD through the first conductive film C1, etc. That is, signals input from the outside of (e.g., received from an external source to) the image sensor and/or output from the image sensor may be interfaced by the rear vias BV and the rear conductive pads PAD, but the example embodiments are not limited thereto.

Referring to FIG. 5, one or more micro lenses ML may be arranged on the color filters CF1 and/or CF2, etc., in the pixel array region APS. Edges of the micro lenses ML may be in contact with and connected to each other, but are not limited thereto. The micro lenses ML may be arranged in an array. The micro lenses ML may also be referred to as a “micro lens array.”

The lens residual layer MLR may be on and/or disposed on the light-blocking structure OBL in the edge region ER, etc. The lens residual layer MLR may include the same material as the micro lenses ML, but is not limited thereto. An opening 35, through which the rear conductive pad PAD is exposed, may be formed in the lens residual layer MLR and/or the protective film 56 of the pad region PR, etc.

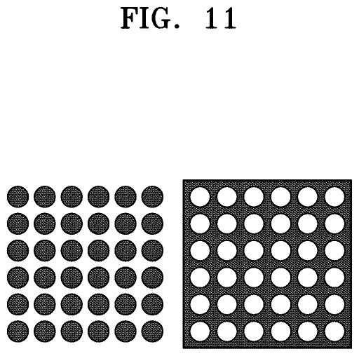

FIG. 11 is a plan view showing a pattern of a second conductive film of a light-blocking structure OBL according to at least one example embodiment.

Referring to FIG. 11, a pattern may be embossed and/or engraved in the second conductive film C2 of the light-blocking structure OBL having the MIM. A wavelength band of light absorbed due to a plasmonic phenomenon occurring in the second conductive film C2 may be selectively adjusted using the pattern described above. Although the pattern of the second conductive film C2 is shown only as a circular shape in FIG. 11, the pattern may have, for example, any one of a triangular shape, a quadrangular shape, and a slit shape, and/or a complex pattern of two or more shapes, etc.

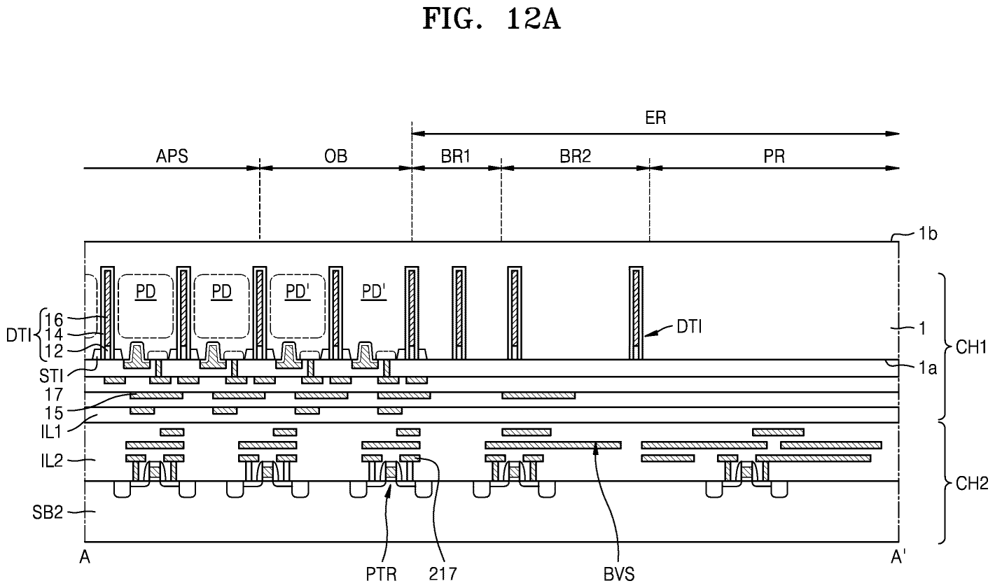

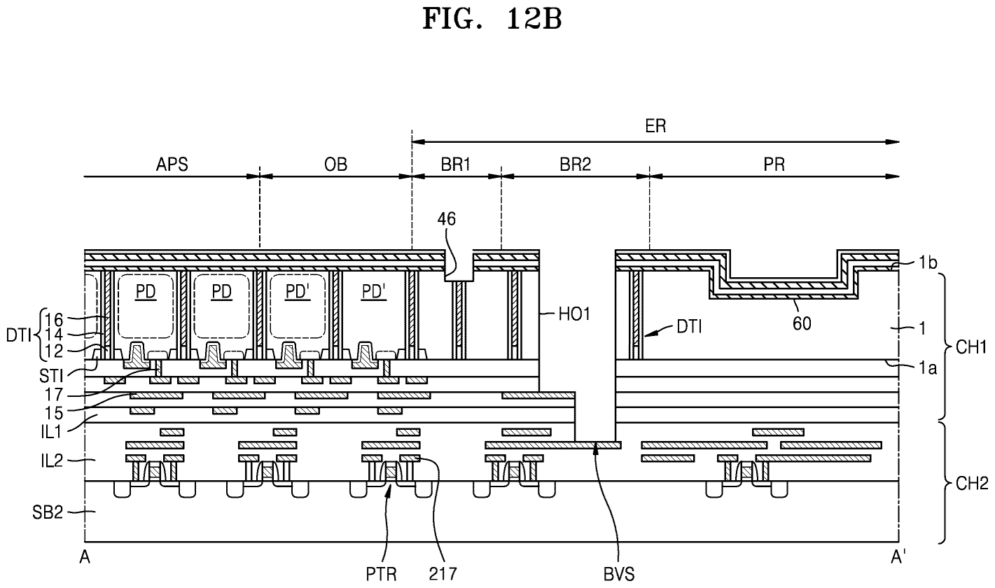

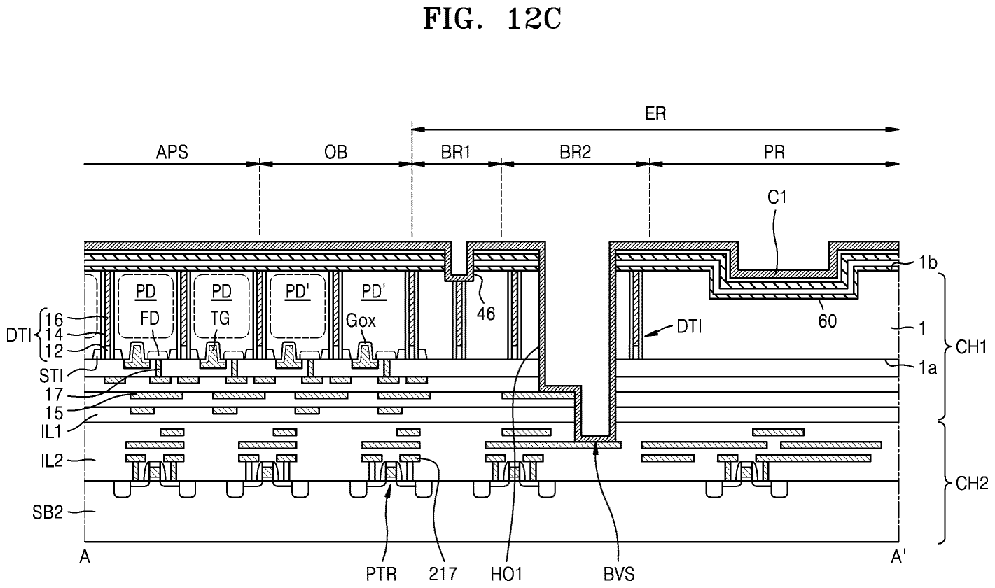

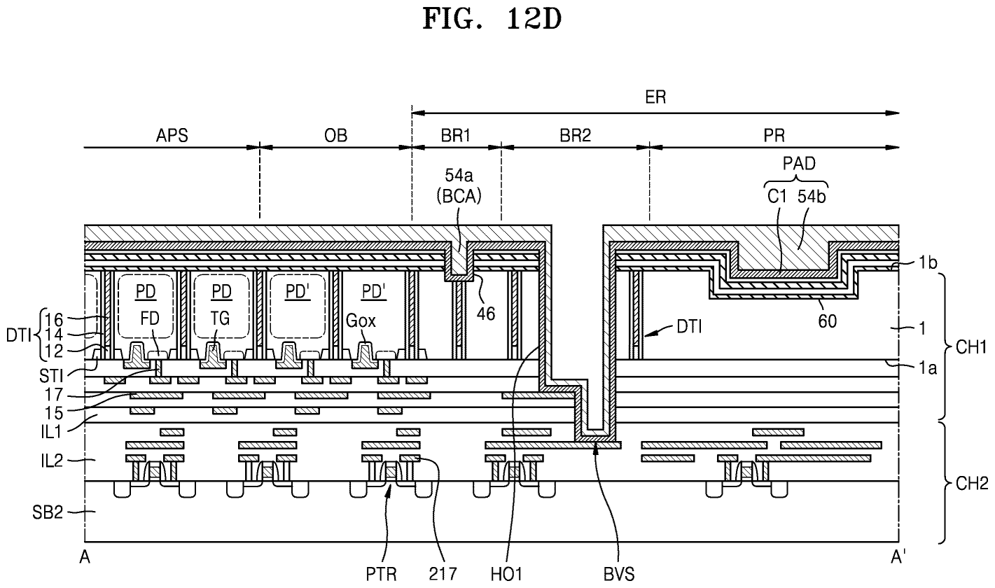

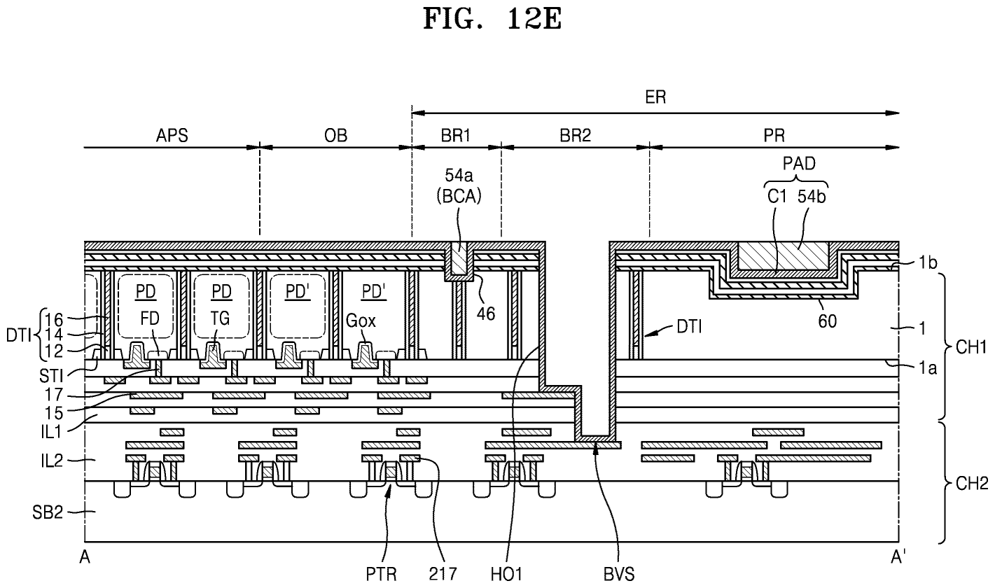

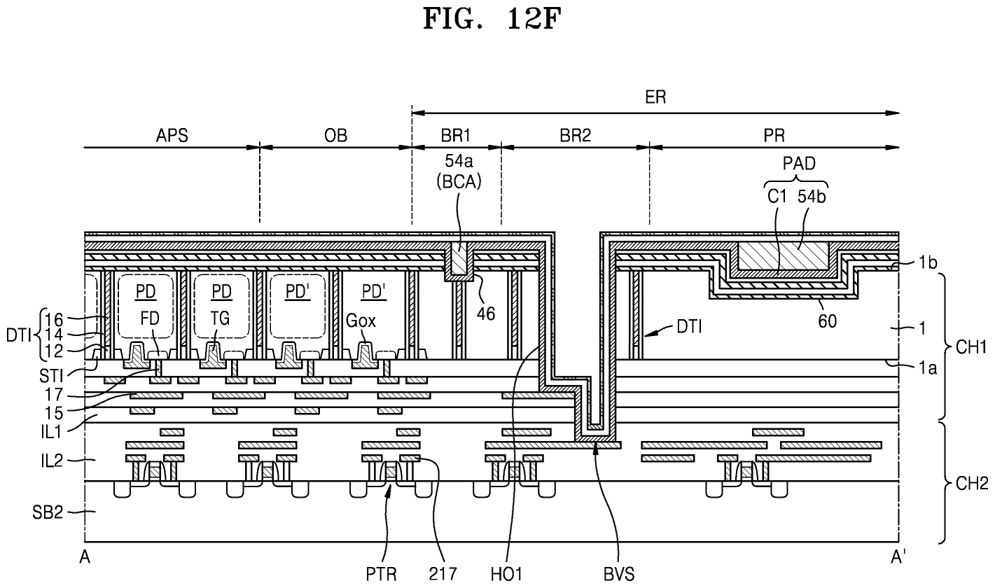

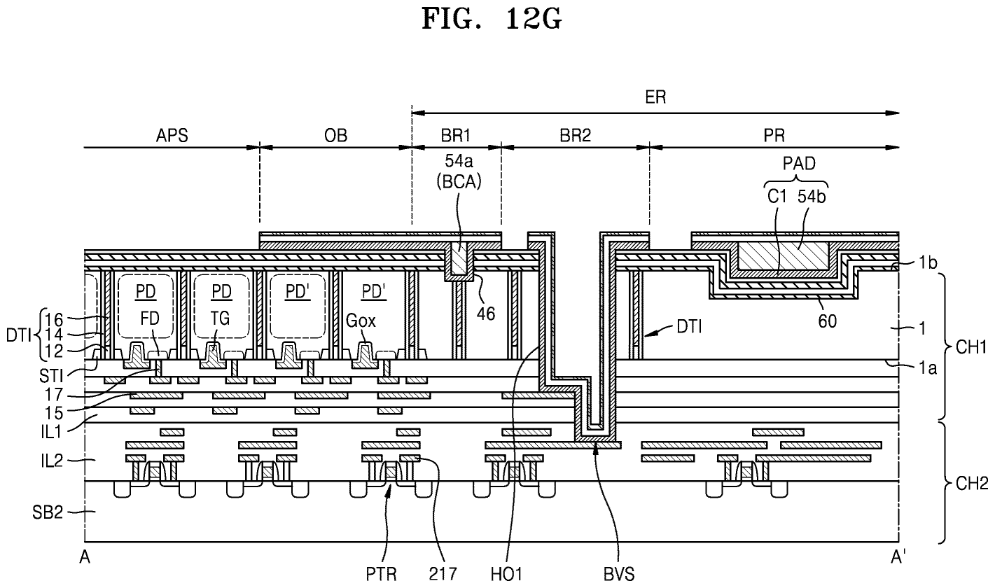

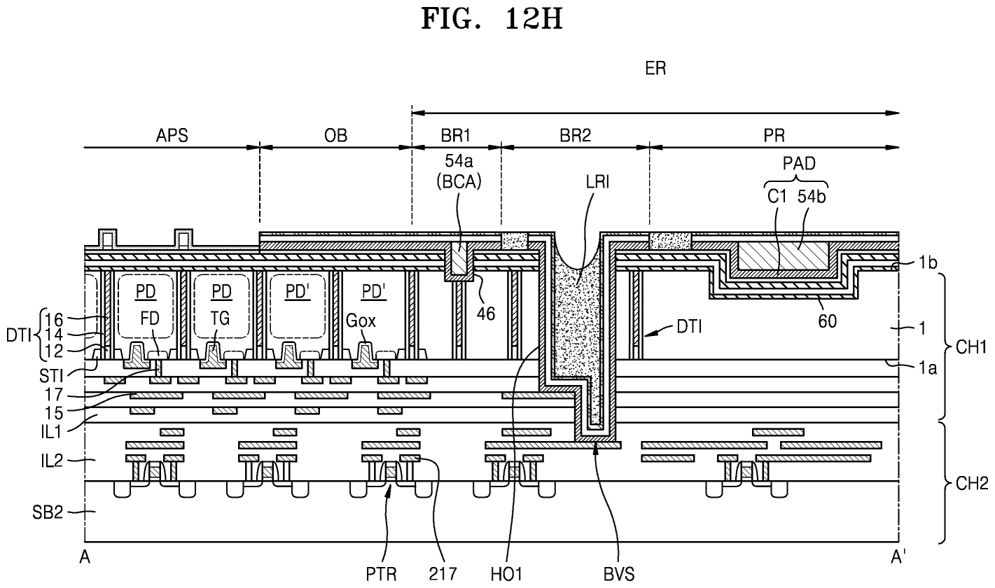

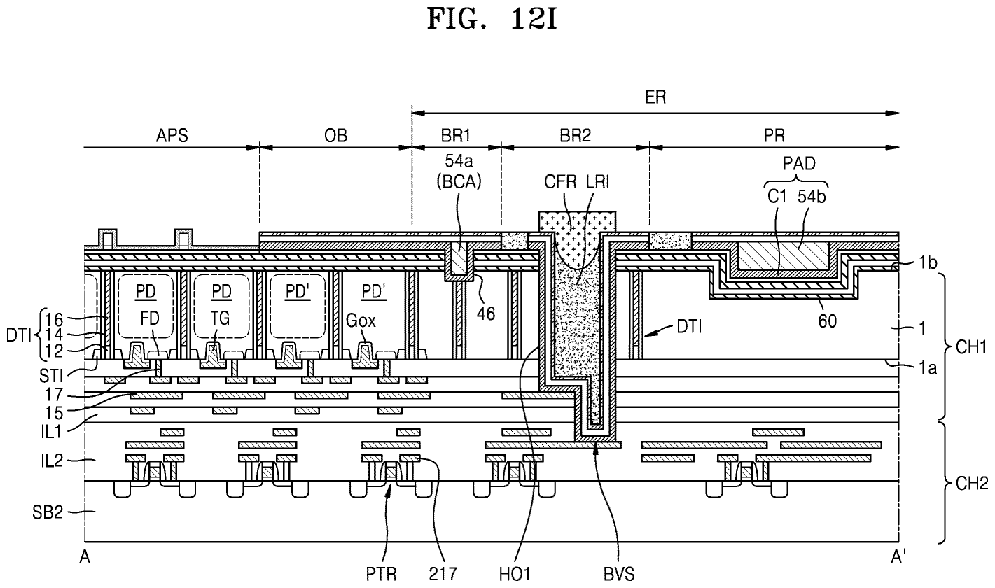

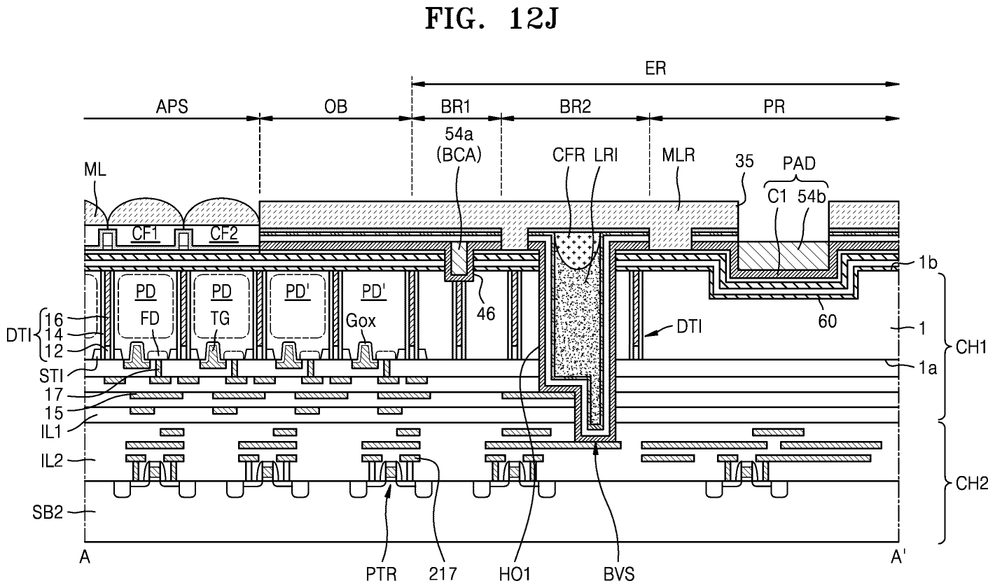

FIGS. 12A to 12J are cross-sectional views sequentially showing a method of manufacturing the image sensor 100 having the cross-section of FIG. 5, according to at least one example embodiment. A description is given below with reference to FIGS. 5 to 7 and 10, but the example embodiments are not limited thereto.

Referring to FIG. 12A, the first sub chip CH1 is manufactured. To this end, first, the clement isolators STI defining an active region, the pixel isolators DTI defining a unit pixel region, and/or the photoelectric converters PD and PD′, etc., are formed in the first substrate 1 including the pixel array region APS and the edge region ER by performing an ion implantation process or the like. Transistors included in the unit pixel UP are formed in the active region. Subsequently, the first interlayer insulating film IL1, the first contact plugs 17, and/or the first lines 15, etc., are formed on the front surface la of the first substrate 1.

The second sub chip CH2 is prepared in which the second interlayer insulating film IL2, the second lines 217 in the second interlayer insulating film IL2, and/or the transistors, etc., on the second substrate SB2 are formed. The first interlayer insulating film IL1 is brought into contact and aligned with the second interlayer insulating film IL2, and the first sub chip CH1 is bonded to the second sub chip CH2 by performing a thermocompression process, but the example embodiments are not limited thereto.

Referring to FIG. 12B, the thickness of the first substrate 1 may be set and/or secured by performing a grinding process, for example, a chemical mechanical polishing (CMP) process, etc., on the rear surface 1b of the first substrate 1 in the state of FIG. 12A. At this time, isolation conductive patterns 16 of the pixel isolators DTI may be exposed. In order to form a buried pad on the rear surface 1b of the first substrate 1 in the pad region PR of the edge region ER, a portion of the first substrate 1 may be etched to form the second rear trench 60. Subsequently, a plurality of insulating films of the anti-reflection structure ARL, that is, the first insulating film A1, the second insulating film A2, the third insulating film A3, and the fourth insulating film A4 are sequentially stacked on each other. Each of the first to fourth insulating films A1 to A4 may be formed by, for example, atomic layer deposition (ALD), chemical vapor deposition (CVD), and/or physical vapor deposition (PVD), etc. The first insulating film A1 may include aluminum oxide (AlO), the second insulating film A2 may include titanium oxide (TiO2), the third insulating film A3 may include silicon oxide (SiO), and/or the fourth insulating film A4 may include hafnium oxide (HfO), but the example embodiments are not limited thereto, and other materials may be used.

In the contact region BR1, the anti-reflection structure ARL and a portion of the first substrate 1 are etched to form the first rear trench 46. When the first rear trench 46 is formed, the pixel isolator DTI may be partially etched to expose the isolation conductive pattern 16 of the pixel isolator DTI. In addition, the anti-reflection structure ARL, the first substrate 1, the first interlayer insulating film IL1, and/or a portion of the second interlayer insulating film IL2 are etched in the rear via stack region BR2 to form the first holes HO1 for the rear via stack BVS. Referring to FIG. 4, second holes for the rear vias BV may be formed around the second rear trench 60 in the pad region PR, but the example embodiments are not limited thereto.

Referring to FIGS. 12C to 12E, the barrier metal BMI and the first conductive film C1 are conformally formed in this order on the rear surface 1b of the first substrate 1 in the pixel array region APS and the edge region ER. The barrier metal BMI may include titanium (Ti) and the first conductive film C1 may include tungsten (W), but the example embodiments are not limited thereto. The first conductive film C1 includes a lower metal of the MIM resonator of the light-blocking structure OBL according to at least one example embodiment of the inventive concepts. Subsequently, conductive films including at least aluminum are sequentially deposited to form metal patterns 54a and 54b, but the example embodiments are not limited thereto, and other metals and/or metal alloys may be used. The metal patterns 54a and 54b may be formed in the first and second rear trenches 46 and 60 of the contact region BR1 and the pad region PR, respectively, through dry etching. The conductive films include titanium nitride/aluminum/titanium nitride (TiN/Al/TiN), but are not limited thereto.

Referring to FIG. 12F, silicon oxide as the first insulating film I1 of the MIM resonator and titanium (Ti) as the second conductive film C2 are deposited (and/or continuously deposited) in the pixel array region APS and/or the edge region ER, etc., but the example embodiments are not limited thereto. Subsequently, hafnium oxide (HfOx), which is the anti-reflection film AR1, is deposited on the entire surface of the second conductive film C2, but the example embodiments are not limited thereto. In this case, at least the first insulating film I1 and/or the second conductive film C2 may also be deposited on the first conductive film C1 in the first holes HOI of the rear via stack region BR2. Although not illustrated, at least the first insulating film I1 and the second conductive film C2 may be deposited on the first conductive film C1 even in second holes of rear vias.

Referring to FIG. 12G, the light-blocking structure OBL including the first conductive film C1, the first insulating film I1, and/or the second conductive film C2, etc., which are included in the MIM formed in the pixel array region APS, is removed. Also, in order to electrically block a rear conductive pad PAD of the pad region PR and the rear via stack BVS of the rear via stack region BR2, the light-blocking structure OBL therebetween may be removed. In order to electrically block the rear contacts BCA of the contact region BR1 and the rear via stack BVS of the rear via stack region BR2, the light-blocking structure OBL therebetween may be removed.

Referring to FIGS. 12H and 12I, a grid pattern may be formed only in the pixel array region APS (e.g., exclusively in the pixel array region APS), but the example embodiments are not limited thereto. The grid pattern may be formed by depositing and/or patterning multi-layers of Ti/TiN/LK as the light-blocking grid pattern 48a and/or the low refractive index grid pattern 50a, etc. Here, LK may represent a low refractive index material, but the example embodiments are not limited thereto. The grid pattern may vertically overlap the pixel isolator DTI. Also, LK may fill regions from which the light-blocking structure OBL has been removed and the inside of the first holes HO1. LK in the first holes HO1 may have a low refractive index protective pattern LRI. Subsequently, the protective film 56 is formed in the pixel array region APS and/or the light-blocking region OB, and the capping pattern CFR may be formed using a negative photoresist, but is not limited thereto.

Referring to FIG. 12J, the color filters CF1 and CF2 may be formed only in the pixel array region APS (e.g., exclusively in the pixel array region APS), but the example embodiments are not limited thereto. That is, the color filter does not exist in the light-blocking region OB, etc. Subsequently, at least one layer for forming at least one microlens is formed. A microlens ML may be formed in the pixel array region APS, and the lens residual layer MLR may be formed in other regions, etc. Subsequently, the lens residual layer MLR, the protective film 56, and the like may be removed from the pad region PR to form the opening 35 through which the rear conductive pad PAD having aluminum is exposed.

The image sensor including the light-blocking structure of the MIM resonator according to some example embodiments of the inventive concepts described above may decrease and/or prevent a flare phenomenon that damages and/or degrades image signals due to reflection of light in the light-blocking region. In addition, the light incident to the light-blocking region is absorbed by the light-blocking structure of the MIM resonator to thereby decrease and/or minimize light transmission. Accordingly, it is possible to decrease and/or prevent deterioration of the characteristics of pixels of the light-blocking region generating the dark level signal, or in other words, improve the image quality of the image sensor.

While various example embodiments of the inventive concepts have been particularly shown and described, it will be understood that various changes in form and details may be made therein without departing from the spirit and scope of the following claims.

1. An image sensor comprising:
a first substrate including a first surface and a second surface, the first surface including a plurality of transistors, and the second surface being opposite to the first surface and configured to receive light, the first substrate comprising a pixel array region and a light-blocking region;
an anti-reflection structure on the second surface of the first substrate in the pixel array region and the light-blocking region; and
a light-blocking structure on the anti-reflection structure in the light-blocking region,
wherein the light-blocking structure comprises a plurality of film that are sequentially stacked, the plurality of film including at least a first conductive film, a first insulating film, and a second conductive film.

2. The image sensor of claim 1, wherein
a thickness of the first conductive film is greater than a thickness of the second conductive film; and
a thickness of the first insulating film is greater than the thickness of the second conductive film.

3. The image sensor of claim 2, wherein
the first conductive film comprises tungsten);
the first insulating film comprises silicon oxide; and
the second conductive film comprises titanium.

4. The image sensor of claim 3, wherein
the thickness of the first conductive film is 150 nm or more;
the thickness of the second conductive film is 10 nm or less; and
the thickness of the first insulating film is approximately 70 nm to approximately 130 nm.

5. The image sensor of claim 3, wherein the light-blocking structure further comprises an anti-reflection film on the second conductive film.

6. The image sensor of claim 5, wherein
the anti-reflection film comprises hafnium oxide;
the light-blocking structure is configured to absorb light of a desired wavelength; and
a thickness of the anti-reflection film corresponds to ¼ of the desired wavelength.

7. The image sensor of claim 5, wherein
a thickness of the anti-reflection film is less than the thickness of the second conductive film; and
the anti-reflection film comprises hafnium oxide.

8. The image sensor of claim 5, wherein
the anti-reflection structure comprises at least three different insulating films stacked on each other; and
the image sensor further comprises a barrier metal between the anti-reflection structure and the light-blocking structure.

9. An image sensor comprising:
a first substrate including a first surface and a second surface, the first surface including a plurality of transistors, and the second surface is opposite to the first surface and is configured to receive light, the first substrate comprising a pixel array region and a light-blocking region;
an anti-reflection structure on the second surface of the first substrate in the pixel array region and the light-blocking region; and
a light-blocking structure on the anti-reflection structure in the light-blocking region,
wherein the light-blocking structure comprises a plurality of film that are sequentially stacked, the plurality of film including at least a first conductive film, a first insulating film, and a second conductive film, and
a plurality of color filters including filters of at least two colors, the plurality of color filters on the anti-reflection structure in the pixel array region, and the plurality of color filters are not on the light-blocking region.

10. The image sensor of claim 9, wherein a height of the plurality of color filters from the second surface of the first substrate is the same as a height of the light-blocking structure from the second surface of the first substrate.

11. The image sensor of claim 9, wherein
a grid pattern between the color filters on the anti-reflection structure; and
the grid pattern comprises a light-blocking grid pattern and a low refractive index grid, the light-blocking grid pattern including metal components, and the low refractive index grid pattern including insulating components.

12. The image sensor of claim 11, further comprising:
a protective film on the grid pattern and the light-blocking structure.

13. An image sensor comprising:
a first substrate including a first surface and a second surface, the first surface including a plurality of transistors, and the second surface opposite to the first surface and configured to receive light, the first substrate comprising a pixel array region and a light-blocking region;
an anti-reflection structure on the second surface of the first substrate in the pixel array region and the light-blocking region;
a light-blocking structure on the anti-reflection structure in the light-blocking region,
the light-blocking structure comprising a plurality of film that are sequentially stacked, the plurality of film including at least a first conductive film, a first insulating film, and a second conductive film;
a pixel isolation film configured to isolate photodiodes of unit pixels included in the first substrate of the pixel array region and the light-blocking region; and
a contact region adjacent to the light-blocking region of the second surface of the first substrate, and
the first conductive film is connected to a conductive pattern of the pixel isolation film in the contact region.

14. The image sensor of claim 13, further comprising:
a first interlayer insulating film below the first surface of the first substrate;
a first wiring layer inside the first interlayer insulating film;
a second interlayer film below the first interlayer insulating film and above a second substrate; and
a second wiring layer inside the second interlayer film; wherein
a via stack region is adjacent to the contact region, and
the via stack region comprises a via stack that passes through the anti-reflection structure, the first substrate, and the first interlayer insulating film to connect the first wiring layer to the second wiring layer using the first conductive film of the via stack in the via stack region.

15. The image sensor of claim 14, wherein the first insulating film and the second conductive film are on the first conductive film in the via stack region.

16. The image sensor of claim 15, wherein the conductive pattern of the pixel isolation film is configured to receive a ground voltage or a negative voltage through the first conductive film.

17. The image sensor of claim 16, wherein
a pad region adjacent to the via stack region of the second surface of the first substrate, and
the pad region comprises the anti-reflection structure, the first conductive film, and a pad metal in sequential order on the second surface of the first substrate, and the pad region further comprises the first insulating film and the second conductive film on the first conductive film.

18.-21. (canceled)
